(19) United States
(12) Patent Application Publication
(10) Pub. No.: US 2026/0150237 A1
(43) Pub. Date: May 28, 2026

(54) MODULAR AIR-COOLED COOLANT DISTRIBUTION SYSTEM FOR LIQUID COOLING OF COMPUTING SYSTEMS

(71) Applicant: Amazon Technologies, Inc., Seattle, WA (US)

(72) Inventors: Thomas Yun, Fairfax, VA (US); Saurabh Kumar Shrivastava, Sammamish, WA (US); Anosh Porus Wadia, Broadlands, VA (US); Michael William Pao, Powell, OH (US); David James Klusas, Powell, OH (US); Trey Wiederhold, Liberty Hill, TX (US); Eugene Patrick Brennan, Gainesville, VA (US); Herbert W Hill, Irrigon, OR (US)

(21) Appl. No.: 18/962,802

(22) Filed: Nov. 27, 2024

(51) Int. Cl. H05K 7/20

(52) U.S. Cl. CPC H05K 7/20272; H05K 7/20154; H05K 7/20263; H05K 7/20781

(57) ABSTRACT

A modular system (e.g., for establishing circulation availability of liquid coolant for datacenter components) can include a set of cabinets couplable together to form a coolant loop having a supply side and a return side. The cabinets can include at least one pressure imparting cabinet, at least one coolant distributing cabinet, and/or at least one heat exchanging cabinet. A pump included in a pressure imparting cabinet may circulate coolant through the coolant loop. A manifold included in a coolant distributing cabinet may distribute coolant along the supply side of the coolant loop toward heat-generating components and direct coolant carrying heat from said components into the return side of the coolant loop. A heat exchanger included in a heat exchanging cabinet may be arranged for dissipating heat carried in the coolant loop so as to ready the coolant for use along the supply side.

### BACKGROUND

Often, a large part of the cost of operating a datacenter is related to the datacenter's cooling systems and the total electricity cost. Accordingly, to limit costs from excessive cooling, a space within a datacenter will typically have cooling systems with a maximum capacity corresponding to the heat load expected to be produced by the equipment within that space. However, if the heat load exceeds the expectation (e.g., due to incorrect assumptions about the equipment or due to a later change to equipment that produces a greater heat load), the existing cooling systems may be inadequate and there may be insufficient room where the cooling systems are located to permit expansions to add capacity.

### BRIEF DESCRIPTION OF THE DRAWINGS

Various embodiments in accordance with the present disclosure will be described with reference to the drawings, in which:

FIG. 1 illustrates examples of components that may be implemented within a system to facilitate liquid cooling in accordance with various embodiments;

FIG. 2 illustrates an overhead view of an example of a datacenter implementing the modular system of FIG. 1 in accordance with various embodiments;

FIG. 3 illustrates a perspective view of a rack and associated components that may be used with the system of FIG. 1 in accordance with various embodiments;

FIG. 4 illustrates examples of components that may be included in a coolant distributing cabinet that may be included in the system of FIG. 1 in accordance with various embodiments;

FIG. 5 illustrates examples of components that may be included in a pressure imparting cabinet that may be included in the system of FIG. 1 in accordance with various embodiments;

FIG. 6 illustrates examples of components that may be included in a heat exchanging cabinet that may be included in the system of FIG. 1 in accordance with various embodiments; and

FIG. 7 is a schematic representation of some examples of coolant loops that may be formed for implementation by the system of FIG. 1 in accordance with various embodiments.

### DETAILED DESCRIPTION

Embodiments herein relate to systems that facilitate liquid cooling of computing components or other heat-generating components, such as in datacenters. The systems may be modular and include sub-units that can be combined together in combinations of differing numbers to form coolant loops of differing sizes and capacities, e.g., such that capacity can be readily scaled to accommodate differing clusters of computing components that may have differing heat loads. Generally, the generated coolant loops may enable dissipation of coolant-carried heat into conditioned airflow that may be available within a datacenter, such as cooling airflow directed between cold aisles and hot aisles. In operation, liquid cooling components can be arranged to leverage cooling available from airflow already established in a datacenter and may be implemented in modular sub-units that may enable ready adjustment of one or more operational capacities of resulting liquid cooling loops.

In an illustrative embodiment, the sub-units of the modular system may include heat exchanging cabinets that include heat exchangers arranged in an airflow path. Coolant traveling through the heat exchangers may dissipate heat into and be cooled by cool air that enters from the cold aisle and exits into the hot aisle carrying heat absorbed from the coolant. Increasing the number of heat-exchanging cabinets included in a given loop may accordingly increase a heat dissipating capacity or heat exchanging capacity of the loop (e.g., such that computing components with a higher heat load than others may be suitably cooled by the loop).

Continuing this illustrative embodiment, the sub-units of the modular system may include pressure imparting cabinets that include pumps and/or other suitable components for driving coolant through the loop. Increasing the number of pressure imparting cabinets included in a given loop may accordingly increase a pressure capacity of the loop (e.g., which may enable a greater number of components and/or distance between components to be accommodated for cooling by the coolant loop than by others).

Further continuing this illustrative embodiment, the sub-units of the modular system may include coolant distributing cabinets that may include manifolds for distributing coolant among racks of servers, computing components, or other heat-generating components. For example, coolant provided along a supply side of the loop (e.g., after exiting in a cooled state from the heat-exchanging cabinet(s) and arriving in response to pressure supplied by the pressure imparting cabinet(s)) may be routed through the coolant distributing cabinets to a set of racks. In the racks, the coolant may pass over integrated circuits or other heat-generating components and impart cooling by collecting generated heat. The coolant with the collected heat may be routed back from the racks and through the coolant distributing cabinets into a return side of the loop. The return side of the loop can extend through the various cabinets (e.g., traveling through the coolant distributing cabinets and the pressure imparting cabinets to reach the heat-exchanging cabinets, where the cooling airflow from cold aisle toward the hot aisle can again reduce the temperature of the coolant to a suitable level for introduction anew into the supply side to provide cooling to the rack-mounted components). Increasing the number of coolant distributing cabinets included in a given loop may accordingly increase a coolant distributing capacity of the loop (e.g., which may enable reaching a greater number of racks and/or a greater number of locations in a given set of racks in comparison to other arrangements with fewer coolant distributing cabinets).

In various embodiments, the heat exchanging cabinets, the pressure imparting cabinets, and the coolant distributing cabinets may be included in suitable respective numbers to achieve or exceed respective thresholds for suitable capacities to accommodate differing arrangements of components that may have different heat loads, pressure affecting characteristics, and/or numbers of connections. The system may enable flexibility to accommodate a wide variety of operational constraints and/or characteristics, for example.

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

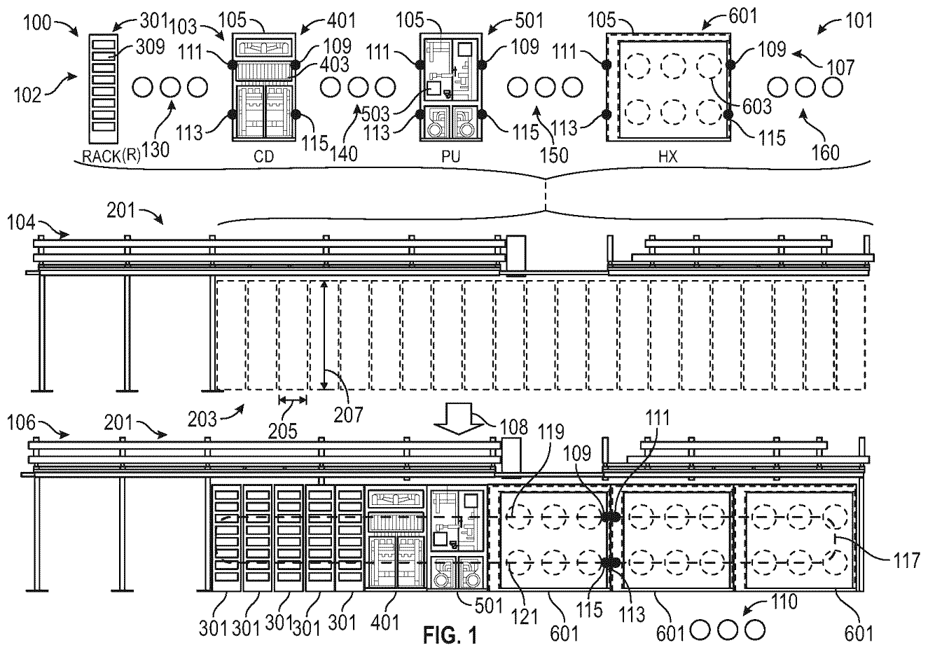

FIG. 1 illustrates examples of components that may be implemented within a system 101 to facilitate liquid cooling in accordance with various embodiments. The system 101 may be modular and thus may alternatively be referred to as a modular system 101 herein.

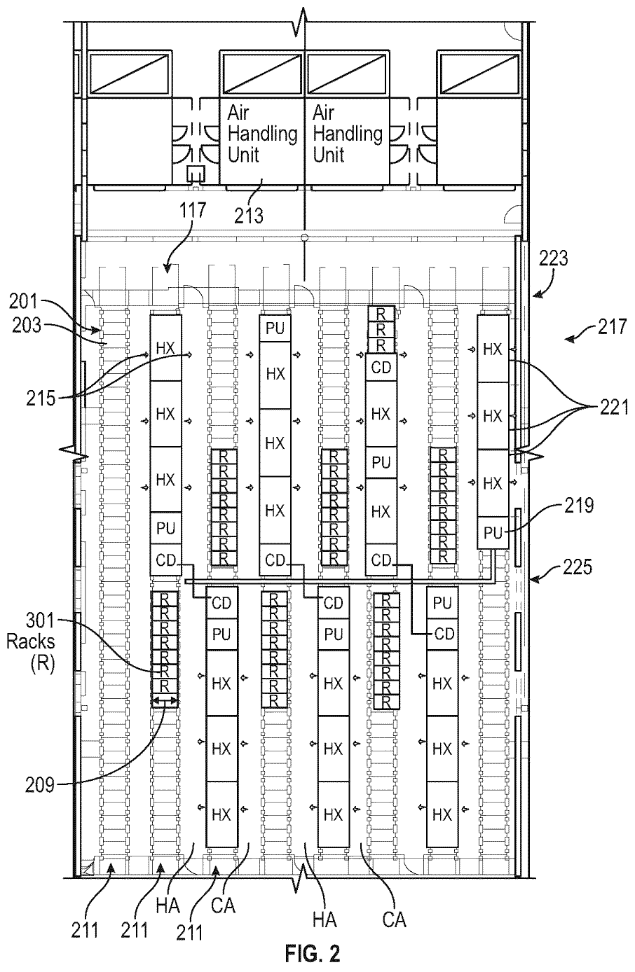

The system 101 may be implemented relative to datacenter infrastructure 201 and/or otherwise utilized within a datacenter (such as, but not limited to, the example of a datacenter 210 depicted in FIG. 2). Although generalized in the depiction in FIG. 1, the datacenter infrastructure 201 may include overhead trays or rails (such as for supporting data cables, power cables, coolant conduits, and/or other lines and/or structures for providing interconnection among components), floors (which may include vents to permit air flow from subfloor ducting and/or panels that may be removable to access subfloor space for routing among datacenter components), vertically extending structures (such as walls or other containment structures for at least partially dividing zones such as hot aisles and cold aisles; columns for supporting overhead structures, walls, lines, etc.; mounting structures; and/or other structures), and/or other suitable structures for facilitating operations of a datacenter.

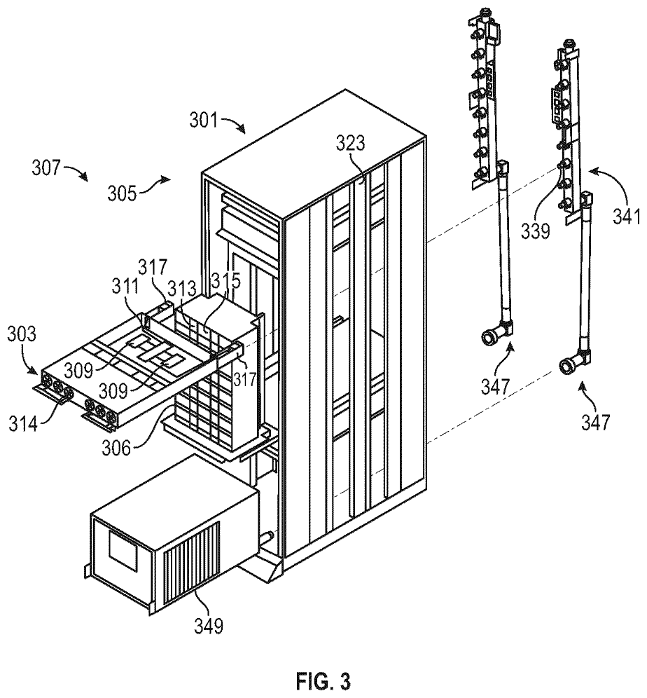

Racks 301 (also abbreviated as R in the figures) may be included, such as individually or in a plurality. The racks 301 may correspond to server racks or other racks suitably arranged for supporting rack-mounted components or appliances 309 (such as servers, network switches, and/or other computing components), which also may be included individually and/or in pluralities. One example of a rack 301 is described herein with respect to FIG. 3.

The datacenter infrastructure 201 may be suitably sized and/or arranged to accommodate the racks 301. The racks 301 may exhibit a uniform and/or predetermined form factor. The datacenter infrastructure 201 may define slots 203 sized to match a form factor of a rack 301. For example, the slots 203 may be sized to match and/or receive a rack width 205. Slots 203 additionally or alternatively may be sized according to a rack height 207 and/or a rack depth 209 (e.g., such as may be more easily seen in the top view of FIG. 2). In some examples, the rack width 205 and rack depth 209 may correspond to a 24 inch by 24 inch footprint, a 24 inch by 48 inch footprint, or any other footprint of a standardized rack 301. In some examples, the rack height 207 may correspond to a 42U or 48U rack (e.g., where each U may correspond to approximately 1.75 inches or 4.45 centimeters pursuant to industry terminology), although other suitable dimensions for the rack height 207 may be utilized.

The modular system 101 may include sub-units that correspond to a set of cabinets 103 that may be utilized together to facilitate provision of liquid cooling relative to the racks 301 and/or rack-mounted components or appliances 309. Different types of cabinets 103 may be utilized with different included components and related functions, which may include those described elsewhere herein. The cabinets 103 in FIG. 1 are shown including coolant distributing cabinets 401 (also abbreviated as CD in the figures), pressure imparting cabinets 501 (also abbreviated as PU in the figures), and heat exchanging cabinets 601 (also abbreviated as HX in the figures), although others may be utilized additionally or alternatively as supplements and/or replacements.

FIG. 1 shows different views that may represent different operations within an implementation process 100. Generally, view 102 illustrates that the process 100 can include selecting and/or accessing components available for installation, view 104 illustrates that the process 100 can include selecting and/or accessing a suitable location for installation, and view 106 illustrates that the process 100 can include selecting and/or installation of a suitable combination of the accessed components for the accessed location. Ellipses in FIG. 1 are utilized to illustrate that different numbers and/or combinations can be utilized. For example, the process 100 at 102 may include selecting a first number 130 of racks 301, a second number 140 of coolant distributing cabinets 401, a third number 150 of pressure imparting cabinets 501, and/or a fourth number 160 of heat exchanging cabinets 601. The selected numbers may be alike or different relative to one another and may include zero, one, or more. The selected numbers may be selected according to a number of slots 203 available in the location selected and/or accessed at view 104. For example, as illustrated by arrow 108, one combination may be installed to occupy all available slots 203 within a particular datacenter infrastructure 201, although ellipse 110 also represents that other combinations of occupying all or fewer than all slots 203 may be utilized. Moreover, although twenty-one slots 203 are shown, other numbers of slots 203 may be utilized. Furthermore, although some examples of sequences or orders of cabinets 103 are shown and described herein, cabinets 103 may be configured to enable coupling together in any suitable sequence or order (e.g., including coolant distributing cabinets 401, pressure imparting cabinets 501, and/or heat exchanging cabinets 601 being arranged upstream or downstream from one another and/or arranged with same types of cabinets 103 clustered together or interspersed among arrangements). Generally, suitable combinations may be included to facilitate liquid cooling for included racks 301.

Various features may be included in common across different forms of cabinets 103. For example, any cabinet 103 may include a shell 105. The shell 105 may include panels, walls, or other frame elements defining and/or bounding an interior volume of the cabinet 103 in which other components may be disposed. The shell 105 may correspond to at least a partial enclosure, which may include a portion being open or openable for access to components within.

The shell 105 may be sized so that outermost boundaries fit within a slot 203 sized to match a single instance of a rack width 205 or a multiple of the rack width 205 (such as double a rack width 205, triple a rack width 205, quadruple a rack width 205, etc.). As examples, in FIG. 1, the coolant distributing cabinets 401 and the pressure imparting cabinets 501 are each shown matching double a rack width 205 while the heat exchanging cabinets 601 are each shown matching quadruple a rack width 205, although other relative sizes may be used additionally or alternatively. Any cabinet 103 may be sized to fit within a rack height 207 and/or a rack depth 209, although in some embodiments, at least some cabinet 103 may be larger in at least one dimension in comparison to the rack width 205, the rack height 207 and/or the rack depth 209 of racks 301 and/or slots 203 included.

Any cabinet 103 may include couplers 107. The couplers 107 may be configured to be connected to one another to facilitate operation among the cabinets 103. The couplers 107 may include suitable structure for facilitating interconnection among structures for carrying data, power, and/or fluid between cabinets 103. As examples that may facilitate fluid flow, the couplers 107 may include a supply inlet 109, a supply outlet 111, a return inlet 113, and a return outlet 115. The couplers 107 may be configured to be connected to one another to establish a coolant loop 117 extending through the cabinets 103. The couplers 107 may be suitably arranged in a uniform and/or consistent manner on each cabinet 103, e.g., to allow any cabinet 103 to be coupled to any other. As illustrative examples, the couplers 107 on a coolant distributing cabinet 401 may be suitable sized and spaced to allow the coolant distributing cabinet 401 along a given side to be connectable interchangeably with another coolant distributing cabinet 401, a pressure imparting cabinet 501, or a heat exchanging cabinet 601. In various embodiments, the couplers 107 and/or other conduit structure can be symmetric, e.g., which may allow bi-directional operation regardless of installation orientation of a given cabinet 103. The couplers 107 may include or be accompanied by valves that may be suitably located and/or configurable to isolate flow, mix flow, stop flow, and/or enable flow, e.g., such that flow can be directed or re-directed through selected pathways to facilitate isolating or utilizing assorted included components during installation, maintenance, and/or operation in use.

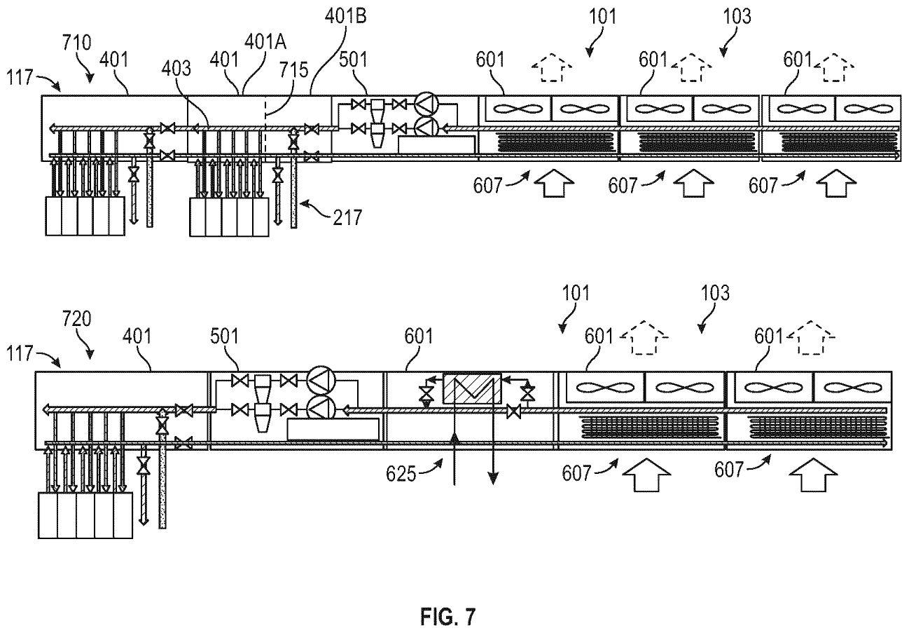

The coolant loop 117 is represented generally and schematically by a dashed line extending through the cabinets 103 and the racks 301 in FIG. 1 (e.g., with a counter-clockwise flow in the depicted view), although any suitable internal routing may be utilized, including, but not limited to examples that may be appreciated with respect to FIG. 7. With reference further to FIG. 1, the coolant loop 117 may include a supply side 119 and a return side 121. The supply side 119 may be utilized to provide coolant in suitable condition to absorb heat from and cool components (such as in the racks 301). The return side 121 may be utilized to return coolant with absorbed heat to a suitable location and/or structure for dissipation, e.g., to ready the coolant for travel and/or use along the supply side 119.

The couplers 107 may connect respective portions of the coolant loop 117. For example, when installed (such as represented at view 106), the supply outlet 111 of one cabinet 103 may be coupled to the supply inlet 109 of another cabinet 103 to establish fluid flow along the supply side 119 of the coolant loop 117. Similarly, the return outlet 115 of one cabinet 103 may be coupled to the return inlet 113 of another cabinet to establish flow along the return side 121 of the coolant loop 117.

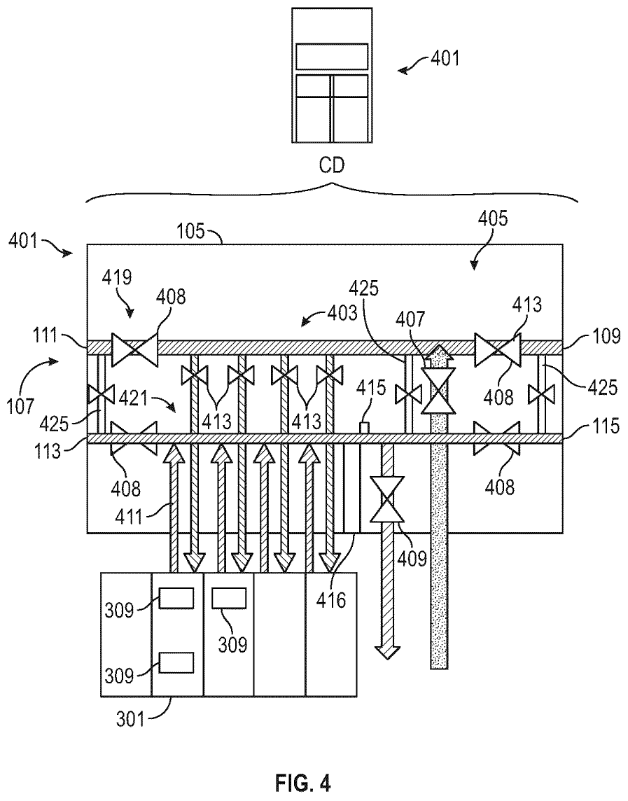

As noted previously, different types of cabinets 103 may be utilized with different included components and related functions. As a first example, at least one coolant distributing cabinet 401 included in the set of cabinets 103 may include a manifold 403 configured to distribute coolant along the supply side 119 of the coolant loop 117 (e.g., toward a plurality of rack-mounted components or appliances 309) and to direct coolant carrying heat from said components into the return side 121 of the coolant loop 117. Examples of features that may be included in the coolant distributing cabinet 401 are discussed with respect to FIG. 4.

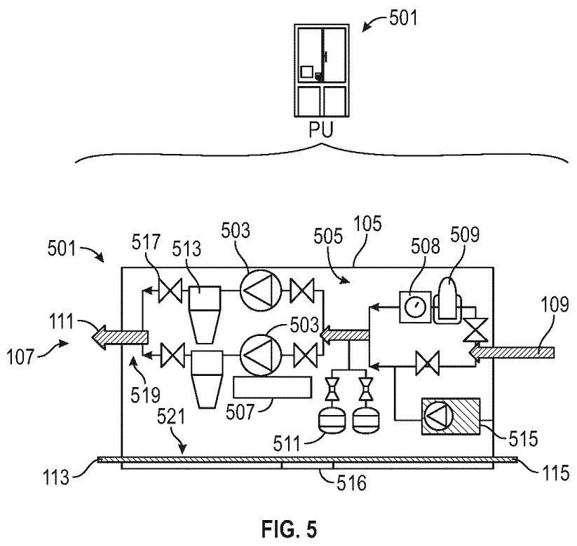

As a second example, at least one pressure imparting cabinet 501 included in the set of cabinets 103 may include a pump 503 configured to circulate coolant through the coolant loop 117. Examples of features that may be included in the pressure imparting cabinet 501 are discussed with respect to FIG. 5.

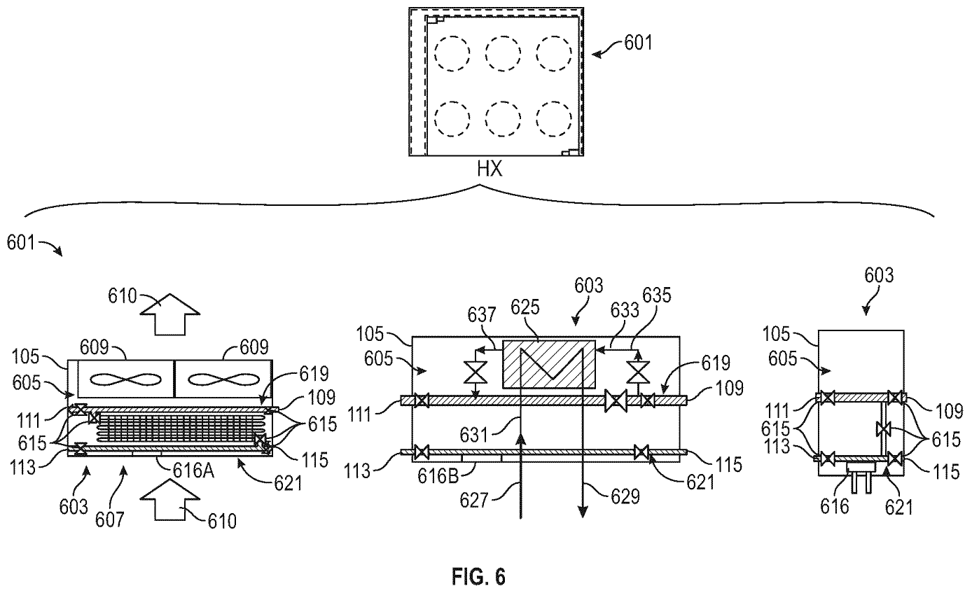

As a third example, at least one heat exchanging cabinet 601 included in the set of cabinets 103 may include a heat exchanger 603 arranged for dissipating heat carried in the coolant loop 117 so as to ready the coolant for travel and/or use along the supply side 119. Examples of features that may be included in the heat exchanging cabinet 601 are discussed with respect to FIG. 6.

Adding (e.g., by installing and/or connecting) different numbers of a given type of cabinet 103 may increase a capacity, which may be useful for different configurations of the coolant loop 117 and/or different numbers and/or types of racks 301 and/or associated rack-mounted components or appliances 309. As one example, adding a first number of coolant distributing cabinets 401 may increase an amount of coolant distributing capacity within the coolant loop 117 (e.g., which may alter how many racks 301 or rack-mounted components or appliances 309 can be serviced by single coolant loop 117). As another example, adding a second number of pressure imparting cabinets 501 may increase an amount of pressure capacity within the coolant loop 117 (e.g., which may accommodate flow rate and/or pumping power specifications of components included). As a further example, adding a third number of heat exchanging cabinets 601 may increase an amount of heat exchanging capacity within the coolant loop 117 (e.g., which may accommodate increasingly larger heat loads that may be encountered with advances in computing capacity of computing components).

FIG. 2 illustrates an overhead view of an example of a datacenter 210 implementing the modular system 101. The datacenter 210 may include datacenter infrastructure 201 that may define rows 211, which may define the slots 203. The rows 211 may be defined between hot aisles (HA) and cold aisles (CA). The cold aisles CA may direct air (such as conditioned air from an air handling unit 213 or other source) across the rows 211 and toward the hot aisles HA, such as illustrated by airflow arrows 215. The datacenter infrastructure 201 may include suitable barriers to establish or maintain boundaries between the cold aisles CA and the hot aisles HA in use. The passage of air (e.g., as at arrows 215) from the cold aisles CA toward the hot aisles may be used to facilitate cooling of components in racks 301.

In various embodiments, the modular system 101 may enable airflow in the datacenter 210 for air-cooled applications to additionally or alternatively be used for carrying away or dissipating heat from liquid cooled applications (e.g., providing cooling to the coolant loop 117 to sufficiently decrease a temperature of coolant supplied along the return side 121 to enable the coolant to be useful for reintroduction into the supply side 119). For example, the cabinets 103 (e.g., individually labeled HX, PU, or CD in FIG. 2) may be configured to be installed in a row 211 between a hot aisle HA and a cold aisle CA of a datacenter 210. The cabinets 103 may be connected to establish a coolant loop 117 (e.g., FIG. 1) extending through the cabinets 103 (e.g., represented in FIG. 2 by the cabinets 103 being arranged together abutting one another). The implemented cabinets 103 may accordingly provide circulation of coolant to associated racks 301, such as in the same row 211 or another row 211 in the datacenter 210. For example, one or more pressure imparting cabinets PU may provide pressure for driving the coolant, while one or more coolant distributing cabinets CD may distribute coolant to and from associated racks 301. In conjunction, one or more included heat exchanging cabinets HX may include a heat exchanger arranged between the hot aisle HA and the cold aisle CA so as to be positioned for receiving cooling air flow directed from the cold aisle CA toward the hot aisle HA. This cooling airflow may be directed relative to components discussed with respect to FIG. 1, such as across the heat exchanger 603 for dissipating heat carried in the coolant loop 117 so as to ready coolant for travel and/or use along the supply side 119. Overall, the modular system 101 may allow for retrofitting a datacenter 210 originally set up for air-cooling to be outfitted for liquid-cooling of racks 301, rack-mounted components and/or appliances 309, and/or other heat-generating components.

Thus, in use in an illustrative example referencing both FIGS. 1 and 2, the system 101 may facilitate implementation of a method or process 100 of establishing circulation availability of liquid coolant (e.g., for datacenter components such as the racks 301 and/or the rack-mounted components or appliances 309). The method or process 100 (e.g., at 102) can include accessing cabinets 103 of a modular system 101 that includes coolant distributing cabinets 401, pressure imparting cabinets 501, and heat exchanging cabinets 601. Each of the cabinets 103 may include couplers 107 that include a supply inlet 109, a supply outlet 111, a return inlet 113, and a return outlet 115. The method (e.g., at 106) can include installing a selected number of cabinets 103 in a row 211 between a hot aisle HA and a cold aisle CA of a datacenter 210. The selected number can include at least a first coolant distributing cabinet CD, at least a first pressure imparting cabinet PU, and at least a first heat exchanging cabinet HX. The method 100 can further include (e.g., further at view 106) connecting the couplers 107 to establish a coolant loop 117 extending through the cabinets 103 and configured to circulate coolant through the loop 117 in response to pressure from a pump 503 in the first pressure imparting cabinet 501 such that coolant travels along a supply side 119 of the coolant loop 117 to one or more racks 301 of components 309 connected with a manifold 403 in the first coolant distributing cabinet 401 and carries heat from said components 309 along a return side 121 of the coolant loop 117 to a heat exchanger 603 in the first heat exchanging cabinet 601 for heat dissipation by receiving cooling air flow directed from the cold aisle CA toward the hot aisle HA across the heat exchanger 603 so as to ready coolant for travel anew along the supply side 119.

In various embodiments, the datacenter 210 further includes a catcher system 217. The catcher system 217 can include at least one catcher pressure imparting cabinet 219 (which may be an example of the pressure imparting cabinet PU) and/or at least one a catcher heat exchanging cabinet 221 (which may be an example of the heat exchanging cabinet HX). Features of the catcher system 217 can be connected in a catcher coolant loop 223, for example. The catcher system 217 can further include or be implemented with a liquid conveying network 225. The liquid conveying network 225 can include a plurality of conduits and valves arranged to selectively fluidly couple the catcher coolant loop 223 with the coolant loop 117 and/or one or more other loops established elsewhere in the datacenter 210 such that the catcher coolant loop 223 is selectively engageable for supplemental capacity of pressure and/or heat exchanging. For example, including the catcher system 217 can allow one set of pressure imparting cabinets PU and/or heat exchanging cabinet HX to serve as a back-up to one or more other coolant loops 117 instead of each coolant loop 117 occupying space to include additional sub-units as available redundancy. Valves for controlling flow from the catcher coolant loop 223 can be included in cabinets 103 of the modular system 101 (such as in the coolant distributing cabinets 401), e.g., such that control can be provided relative to a particular cabinet 103 with a demand for supply from the catcher coolant loop 223.

FIG. 2 also illustrates that any suitable combination and/or order may be implemented in use. As some illustrative examples, referring to different portions of rows upward from the liquid conveying network 225 in the view in FIG. 2, a second row from the left is shown with a coolant distributing cabinet CD, followed by a pressure imparting cabinet PU, and followed by three heat exchanging cabinets HX, while a fourth row from the left is instead shown with a coolant distributing cabinet CD, followed by three heat exchanging cabinets HX, and followed by a pressure imparting cabinet PU. In various examples, including a pressure imparting cabinet PU upstream of one or more heat exchanging cabinets HX may allow pressure drops to be imparted through the one or more heat exchanging cabinets HX and facilitate a reduced inlet pressure into a coolant distributing cabinet CD and/or rack 301 (e.g., which may be beneficial to accommodate inlet pressure limits that may apply to features of a coolant distributing cabinet CD and/or rack 301). More generally, placement of the pressure imparting cabinet PU and a heat exchanging cabinet HX may be interchangeable to optimize or adjust pressure within an arrangement. As another example of variety in arrangements, a sixth row from the left is shown with heat exchanging cabinets HX and coolant distributing cabinets CD arranged outward in series from a centrally positioned pressure imparting cabinet PU. Arranging coolant distributing cabinets CD at opposite ends may enable racks to be supplied from multiple sides of an arrangement. In a second row from the right downward from the liquid conveying network 225 in the view in FIG. 2, an example is shown with a coolant distributing cabinet CD spaced apart from racks R (e.g., with at least one pressure imparting cabinet PU intervening, although at least one heat exchanging cabinet HX may be intervening additionally or alternatively). In some arrangements, a coolant distributing cabinet CD may be coupled with racks R via suitable conduits extending through overhead trays, headers, and/or other structures of the datacenter infrastructure 201.

FIG. 3 illustrates a perspective view of a rack 301 and associated components that may be used with the modular system 101 and/or within the datacenter 210 according to various embodiments. The rack 301 can support any number of chassis 303. For example, although one chassis 303 is shown in FIG. 3 for ease of viewing, any other number could be used, including eight chassis 303, between one and seven, or nine or more.

The rack 301 and/or the chassis 303 may be implemented relative to a system 305 (e.g., which may correspond to a liquid-cooled computing system). The system 305 may include the rack 301, the chassis 303, and/or other components. Various components of the system 305 are shown in exploded view in FIG. 3 for ease of viewing associated structures, although components may be received in and/or along the rack 301 in use. The system 305 may include components of other systems or subsystems.

Suitable components of a cooling system 307 can be included. The cooling system 307 may provide coolant or otherwise provide cooling to components in the chassis 303 within the rack. The coolant may include water or other liquid coolant, for example. However, although description herein focuses primarily on liquid coolant for ease of discussion, it may also be appreciated that any suitable fluid coolant may be utilized, whether in liquid form, gaseous form (such as in scenarios using air-cooling or other gasses), or forms that may switch among different states (such as refrigerants that may be acted on by a compressor or otherwise caused to switch between vapor and liquid phases etc.). Components of the cooling system 307 may be located in or on the rack 301, in or on the chassis 303, or remote and/or separate from both the rack 301 and chassis 303.

The chassis 303 can include and/or interact with other components. The chassis 303 is depicted implemented with an appliance 309, a coolant conduit 311, a power connector 313, a data connector 315, and a coolant connector 317, although more, fewer, and/or other components may be implemented. An example of a subassembly with the appliance 309 (e.g., that may be coupled with the coolant conduit 311) is shown in a position installed in an uninstalled chassis 303, although components may be installed in groups or individually. The power connector 313 and the data connector 315 are depicted as structures on a midplane 306 that may provide connection to other structures coupled with the midplane 306, although the power connector 313 and/or the data connector 315 may correspond to structures in or on the chassis 303 or otherwise arranged to enable communication or interoperability among components in the chassis 303 and other components received in the rack 301 and/or remote from the rack 301.

The appliance 309 may correspond to one or more parts of a computer server, or any other computing equipment component. Examples may include heat-generating or other components that may be borne by the chassis 303. The heat-generating components may correspond to integrated circuits (including chips or dice), or other heat-generating components. Non-limiting examples include a processor, an input/output (I/O) chip, a baseboard management controller, a chip, a die, a card (e.g., which may include a printed circuit board various that bears other components), a voltage regulator, a hot swap control, an inductor, a resistor, or a capacitor). Other non-limiting examples may include a Field Programmable Gate Array (FPGA), a Complex Programmable Logic Device (CPLD), and a System-on-a-Chip (SoC). Each heat-generating component may include one or more subcomponents that generate heat to be carried away or otherwise addressed by the cooling system 307. For example, the coolant conduit 311 of the cooling system 307 may be arranged to provide coolant flow over, by, and/or past the appliance 309 (such as by supplying coolant through cooling plates, heat exchangers, or other suitable structure for absorbing and/or carrying away heat from such heat-generating components).

Various elements of the chassis 303 may facilitate connection of the chassis 303 when the chassis 303 is fully received within the rack 301, such as when the chassis 303 has been moved from an extended position to a seated position. For example, in various embodiments, blind mate connectors may be utilized. Blind mate connectors may allow connection to be established by the act of receiving the chassis 303 or installing the chassis 303 within the rack 301. Any of the power connector 313, the data connector 315, and/or the coolant connector 317 may utilize blind mate connectors. However, in some embodiments, some components may be arranged to be manually connected following installation of the chassis 303 in lieu of or in addition to using blind mate connectors to automatically connect to the chassis 303 upon installation. In various embodiments, installing the chassis 303 within the rack 301 can involve sliding the chassis 303 along a set of one or more rails that are supported by vertical struts 323 of the rack 301 until the chassis 303 is slidingly received in the rack 301. However, other suitable structures may be utilized for facilitating sliding or other movement of the chassis 303 relative to the rack 301 including, but not limited to, bearing elements that may include polished surfaces and/or ball bearings or any other structures suitable for facilitating sliding.

The power connector 313 can correspond to any structure for establishing a power connection. Some examples may include, but are not limited to, a plug with a set of prongs and/or a corresponding socket for receiving the prongs. The power connector 313 may provide connection to a power cable, a power conduit, a power supply unit, a power harness structure, and/or another source of electrical power. The power connector 313 can be coupled with any appropriate wires, traces, or other structures for conveying power from the power connector 313 to the appliance 309 and/or other components of the chassis 303.

The data connector 315 can correspond to any structure capable of establishing a connection for communicating data from, to, or relative to the chassis 303 or components therein. The data connector 315 may form a part of a data connection interface. Suitable examples of types of the data connection interface may include pluggable optical transceivers (such as small form-factor pluggable (SFP), enhanced small form-factor pluggable (SFP+), compact small form-factor pluggable (CSFP), or other variations such as QSFP, QSFP+, QSFP28, QSFP56, QSFP56-DD, or OSFP), interconnect interfaces (such as Ultra path Interconnect (UPI), peripheral component interconnect express (PCIE), an RJ45 connector type or a similar connector type, or a connector sized and arranged to meet any other suitable standards that may be implemented. The data connector 315 may convey data to or from other elements in the rack 301 and/or to or from components that are remote from the rack 301.

The coolant connector 317 can correspond to any suitable structure for establishing a connection through which coolant can be conveyed. The coolant connector 317 may be arranged to engage a port body 339. The coolant connector 317 on the chassis 303 and the port body 339 can together form parts of a coolant connection interface 341. The coolant connection interface 341 may correspond to an anti-leak connection interface. For example, the structures of the coolant connection interface may be arranged to cut off coolant supply when the coolant connector 317 of the chassis 303 is disconnected from the port body 339. Suitable examples may include quick-disconnect or quick-release couplings or fittings that may be commercially available.

The cooling system 307 can include a coolant manifold 347. The port body 339 may be coupled with or form a part of a coolant manifold 347, for example. The coolant manifold 347 may be connected to a coolant module 349, for example, to provide coolant to multiple chassis 303 within the rack 301. The coolant module 349 may correspond to a coolant distribution unit and/or may include suitable heat exchangers, pumps, or other structures for circulating coolant relative to components in a chassis 303 or multiple chassis 303. As an illustrative example in FIG. 3, coolant may flow up through a coolant manifold 347 depicted at the left side of the rack 301 in FIG. 3, through a coolant conduit 311 and two appliances 309 in the chassis 303, and then out and down a second coolant manifold 347 depicted at the right side of the rack 301 in FIG. 3. Other arrangements are also possible, for example, including an arrangement in which coolant is circulated through only one appliance 309 or through more than two appliances 309. As another example, coolant may flow in one coolant connection interface 341 and out through another coolant connection interface on the same side of the chassis 303, for example, if a coolant manifold 347 includes multiple passages in it for circulating coolant.

In various embodiments, the cooling system 307 may additionally or alternatively include fans 314 arranged to drive cooling airflow through the chassis 303. Although shown along a front of the chassis 303, the fans 314 may be included along a rear or other location. The fans 314 may facilitate airflow between a hot aisle HA and a cold aisle CA (FIG. 2). Fans 314 may be included to supplement liquid cooling components and/or may be replaced by liquid cooling components in some arrangements.

In various embodiments, the cooling system 307 includes suitable interfaces for connecting to the coolant loop 117 described elsewhere herein. For example, in some examples the coolant module 349 may be arranged to exchange coolant with the coolant distributing cabinet 401. In some examples, the coolant module 349 may be omitted and structure from the coolant distributing cabinet 401 may directly interface into the coolant manifold 347 along the rack 301 (if present) and/or directly into coolant conduits 311 that provide coolant relative the appliances 309 in the rack 301.

FIG. 4 illustrates examples of components that may be included in a coolant distributing cabinet 401 that may be included in the modular system 101 according to various embodiments. FIG. 4 includes a graphical representation similar to the front view shown in FIG. 1 and also includes a top view that includes a schematic representation of parts that may be included, although variation in placement of components or routing may be implemented.

The coolant distributing cabinet 401 can include a shell 105 defining an internal volume 405. Other parts or features may be positioned within and/or relative to the internal volume 405.

The coolant distributing cabinet 401 can include a supply side portion 419 of a supply side 119 of a coolant loop 117. The supply side portion 419 may be arranged extending within the shell 105 between a supply side inlet 109 and a supply side outlet 111 configured for coupling to extend the coolant loop 117 outside the internal volume 405.

The coolant distributing cabinet 401 can include a return side portion 421 of a return side 121 of the coolant loop 117. The return side portion 421 may be arranged extending within the shell 105 between a return side inlet 113 and a return side outlet 115 configured for coupling to extend the coolant loop 117 outside the internal volume 405.

The coolant distributing cabinet 401 can include a manifold 403. The manifold 403 can be configured to be installed relative to a plurality of rack-mounted components 309 so as to distribute coolant along the supply side 119 of the coolant loop 117 toward said components 309 and to direct coolant carrying heat from said components 309 into the return side 121 of the coolant loop 117. In various embodiments, hard-piped secondary fluid networks (e.g., which may be arranged overhead) may be avoided or eliminated based on the presence or availability of the coolant distributing cabinet 401.

The coolant distributing cabinet 401 may include suitable control valves 408. For example, control valves 408 may be included to enable modulating and/or stopping flow through couplers 107, such as the supply side inlet 109, the supply side outlet 111, the return side inlet 113, and/or return side outlet 115. In some embodiments, including control valves 408 at the supply side outlet 111 and the return side inlet 113 can be useful for allowing the coolant distributing cabinet 401 to alternatively be coupled to extend the coolant loop 117 that can continue in parallel and/or series beyond the shell 105 or to provide a closed end for the coolant loop 117 at which coolant transitions from the supply side 119 to the return side 121 (e.g., based on passage through the appliances 309 and/or racks 301). Valving and connections may be concentrated inside the coolant distributing cabinet 401 and/or allow connections to be made inside the coolant distributing cabinet 401, e.g., which may eliminate connections in an open data center environment where leaks may be particularly problematic. Consolidating components for liquid distribution within the coolant distributing cabinet 401 may provide ease and/or speed in installation, operating, servicing, and/or leakage management.

The coolant distributing cabinet 401 can include a catcher inlet 407 and a catcher outlet 409. These can be arranged to selectively fluidly couple the coolant loop 117 with a catcher coolant loop 223 such that the catcher coolant loop 223 is selectively engageable for supplemental capacity of pressure and/or heat exchanging. Including these valves in the internal volume 405 of the coolant distributing cabinet 401 can facilitate ease of providing access directly at the coolant distributing cabinet 401 at which demand for the catcher system 217 may arise, such as to allow ready switching between a primary coolant loop 117 (e.g., from cabinets 103 in a row) and others (e.g., such as from cabinets 103 in the same or a different row and/or in a remote and/or otherwise distinct catcher system 217). Such valves to provide access to external conduits may allow multiple fluid networks to be combined to achieve redundancy and/or back-feed capability, such as during a failure or maintenance of a subset of the modular system 101. The coolant distributing cabinet 401 may be implemented with multiple piping interfaces and/or a suitable valving system that allows operators or control logic to switch the coolant circulation to a group of racks 301 between different coolant distribution systems (e.g., different coolant loops 117, catcher coolant loops 223, and/or parts thereof). For example, when a coolant distribution system for any row fails, the catcher system 217 may be utilized to back-feed the racks 301 in the failed row, e.g., minimizing downtime and removing single points of failure.

The coolant distributing cabinet 401 can include piping 411 (e.g., which may include rigid tubes and/or flexible hoses). The piping 411 may include and/or be compatible with suitable quick-connect, anti-drip, and/or anti-leak interfaces. The piping 411 can include or be coupled with suitable structure for connecting with a header (e.g., a rigid header) and/or other structure that may be included in overhead trays and/or other components of the datacenter infrastructure 201 that may facilitate routing of conduits relative to racks 301. The piping 411 may be arranged extending between the manifold 403 and the plurality of rack-mounted components 309 so that each rack-mounted component 309 has a supply line providing coolant flow from the supply side 119 of the coolant loop 117 and a return line providing coolant flow with heat from the component 309 into the return side 121 of the coolant loop 117.

The coolant distributing cabinet 401 can include at least one valve 413 configured to modulate flow rate between (e.g., to and/or from) the coolant distributing cabinet 401 and at least one rack-mounted component 309. For example, this can allow flow rate to be modulated in response to differing heat loads or other characteristics among the rack-mounted components 309.

The coolant distributing cabinet 401 can include at least one mixing valve 413 configured to modulate amounts of flow at different temperatures to control output coolant toward a target temperature. For example, different streams may be introduced through the supply inlet 109 and mixed toward a target level.

The coolant distributing cabinet 401 can include at least one sensor 415. The sensor 415 may be configured to provide information about temperature in the return side 121 to facilitate downstream modulation of a heat exchanger 603 in a different cabinet 103. For example, if a spike or other temperature elevated above a threshold amount is detected in the coolant distributing cabinet 401, it may allow time while coolant is flowing therefrom toward the heat exchanger 603 to control components associated with the heat exchanger 603 to increase heat dissipation at the heat exchanger 603 so that coolant can be adequately cooled for subsequent use in the supply side 119.

The coolant distributing cabinet 401 can include at least one bypass line 425 (e.g., which may form part of a loop). The bypass line 425 may include a suitably placed set of one or more conduits and/or valves that may allow the coolant distributing cabinet 401 and/or other elements of the modular system 101 (e.g., the system as a whole) to be commissioned without requiring any external connections to racks or piping. Commissioning can include pump flow rate testing, fan airflow testing, sensor(s) testing, etc. In an illustrative example, the bypass line 425 may be used to prevent flow from reaching the racks 301 or another set of features while flow may be routed through portions of the coolant loop 117 suitable for testing different parameters, and then after testing is completed, the bypass line 425 can be reconfigured to allow flow to proceed to include previously isolated areas.

FIG. 5 illustrates examples of components that may be included in a pressure imparting cabinet 501 that may be included in the modular system 101 according to various embodiments. FIG. 5 includes a graphical representation similar to the front view shown in FIG. 1 and also includes a top view that includes a schematic representation of parts that may be included, although variation in placement of components or routing may be implemented.

The pressure imparting cabinet 501 can include a shell 105 defining an internal volume 505. Other parts or features may be positioned within and/or relative to the internal volume 505.

The pressure imparting cabinet 501 can include a supply side portion 519 of a supply side 119 of a coolant loop 117. The supply side portion 519 may be arranged extending within the shell 105 between a supply side inlet 109 and a supply side outlet 111 configured for coupling to extend the coolant loop 117 outside the internal volume 505.

The pressure imparting cabinet 501 can include a return side portion 521 of a return side 121 of the coolant loop 117. The return side portion 521 may be arranged extending within the shell 105 between a return side inlet 113 and a return side outlet 115 configured for coupling to extend the coolant loop outside the internal volume 505.

The pressure imparting cabinet 501 can include a pump 503 located within the internal volume 505. The pump 503 can be included in the supply side portion 519 or the return side portion 521. The pump 503 can be configured to circulate coolant through the coolant loop 117. In some embodiments, multiple pumps 503 can be included, such as in parallel or serially, such as for redundancy and/or added pressure capacity.

The pressure imparting cabinet 501 can include a controller 507. The controller 507 may be within the internal volume 505. The controller 507 may be configured for controlling at least one of components within the internal volume 505 or components in another cabinet 103 couplable with the pressure imparting cabinet 501. For example, consolidating system-wide control components, input/output devices, and/or other electronics for functions of the controller 507 within the pressure imparting cabinet 501 may reduce a number and/or cost of electronics to be included in other cabinets 103. In some embodiments, the controller 507 may provide a virtual backdraft damper control to ensure airflow is going in the right direction. In some embodiments, the controller 507 may provide a look up table for rack layouts to auto calculate a pump differential pressure and fan speed (and/or other criteria for operations).

The pressure imparting cabinet 501 can include one or more monitoring sensors 508. The sensor 508 may be configured to measure at least one of coolant quality, pressure, temperature, or flow rate, for example.

The pressure imparting cabinet 501 can include other components such as an air separator 509, an expansion tank 511, a filter 513, a coolant filling system 515 (e.g., which may include a dedicated pump, tank, drain connection, and/or other combination of components that may allow coolant to be added or removed from the coolant loop 117), and/or a set of valves 517 configured for balancing flow among differing paths.

FIG. 6 illustrates examples of components that may be included in a heat exchanging cabinet 601 that may be included in the modular system 101 according to various embodiments. FIG. 6 includes a graphical representation similar to the front view shown in FIG. 1 and also includes a top view that includes a schematic representation of parts that may be included, although variation in placement of components or routing may be implemented.

The heat exchanging cabinet 601 may include a shell 105 defining an internal volume 605. Other parts or features may be positioned within and/or relative to the internal volume 505.

The heat exchanging cabinet 601 may include a supply side portion 619 of a supply side 119 of a coolant loop 117. The supply side portion 419 may be arranged extending within the shell 105 between a supply side inlet 109 and a supply side outlet 111 configured for coupling to extend the coolant loop 117 outside the internal volume 605.

The heat exchanging cabinet 601 may include a return side portion 621 of a return side 121 of the coolant loop 117. The return side portion 621 may be arranged extending within the shell 105 between a return side inlet 113 and a return side outlet 115 configured for coupling to extend the coolant loop 117 outside the internal volume 605.

The heat exchanging cabinet 601 may include a heat exchanger 603 located within the internal volume 605 and arranged for dissipating heat carried in the coolant loop 117. For example, the heat exchanger 603 may dissipate heat along the return side 121, along the supply side 119, between the return side 121 and the supply side 119, and/or in any suitable location or combination of locations so as to ready the coolant for travel and/or use along the supply side 119. Stated another way, the heat exchanging cabinet 601 may provide cooling to the coolant in the coolant loop 117, e.g., to ready the coolant for downstream use within the coolant loop 117 and/or so that the coolant is in suitable condition for in turn providing cooling to other components.

Three different options for forms of heat exchanger 603 are shown in FIG. 6. The heat exchanger 603 may correspond to a liquid to air heat exchanger 607, as at left, for example. The liquid to air heat exchanger 607 may be arranged to facilitate heat dissipation during coolant travel between the return side 121 and the supply side 119, for example. The liquid to air heat exchanger 607 may include finned tube or other types.

The heat exchanging cabinet 601 may include a fan 609 positioned to draw air (e.g., as illustrated by arrows 610) across the heat exchanger 603 (e.g., across the liquid to air heat exchanger 607). The fan 609 may be positioned to draw air from a cold aisle CA of a datacenter 210, across the heat exchanger 603 (e.g., across the liquid to air heat exchanger 607), and into a hot aisle HA of the datacenter 210. In various embodiments, utilizing a heat exchanging cabinet 601 that includes a heat exchanger 603 without also including other components for the coolant loop 117 (such as a pump 503 or manifold 403) may allow an increased space for the fan 609 than in an arrangement that includes all structure for a coolant loop 117 within a single cabinet 103 to be fit within a given multiple of a profile of a rack 301. The increased space may allow utilization of larger fans than may be used in other datacenter arrangements (such as allowing use of alternating current (AC) fans that may be larger compared to smaller direct current (DC) fans that may be prominent in racks 301). Some benefits of utilizing larger AC fans may include potential fan power savings, wider range of external static pressure (ESP), fewer parts and connections, and/or reduced acoustic noise.

In some embodiments, the fan 609 may be adjustable to modulate airflow across the heat exchanger 603 (e.g., across the liquid to air heat exchanger 607). In some embodiments, the fan 609 is adjustable to modulate an amount of cooling imparted by the heat exchanger 603 (e.g., across the liquid to air heat exchanger 607). For example, the fan 609 may be adjustable in response to a sensor positioned upstream in a different cabinet 103 (e.g., on a return side 121, such as the sensor 415 described for the coolant distributing cabinet 401).

In various embodiments, control valves 615 may be included in suitable locations to facilitate different functions and/or changes in function of the heat exchanging cabinet 601. In some embodiments, the heat exchanging cabinet 601 may include a control valve 615 for the return outlet 115 (e.g., a return outlet valve) and a control valve 615 for the supply inlet 109 (e.g., a supply inlet valve) that may be operable so that when both closed, an end of the coolant loop 117 is formed by the heat exchanging cabinet 601. In some embodiments, control valves 615 may be included for the return inlet 113 and/or the supply outlet 111 additionally or alternatively. In some embodiments, control valves 615 may be included and operable to prevent or reduce flow through the heat exchanger 603, such as to bypass the heat exchanger 603 (e.g., if the heat exchanging capacity of the heat exchanging cabinet 601 is not needed or is faulty) and/or to direct coolant through primarily or solely through the supply side portion 619 and the return side portion 621.

Additionally or alternatively, the heat exchanger 603 may correspond to a liquid to liquid heat exchanger 625, as at middle in FIG. 6, for example. Features described with respect to the liquid to air heat exchanger 607 may additionally or alternatively be implemented with the liquid to liquid heat exchanger 625 and thus various reference numbers are repeated without duplication of associated description for sake of conciseness.

The liquid to liquid heat exchanger 625 may include a primary side that is looped with an external cold liquid source (e.g. a chiller), which may provide trim-cooling when warranted or may be bypassed when not. For example, on one hand, when cooling capacity of a group of one or more liquid to air heat exchangers 607 in a coolant loop 117 is sufficient to achieve a target supply temperature, the coolant may bypass the liquid to liquid heat exchanger 625. On the other hand, coolant may be directed through the liquid to liquid heat exchanger 625 to provide additional cooling capacity, such as if cooling capacity of a group of one or more liquid to air heat exchangers 607 in a coolant loop 117 is insufficient to lower coolant temperature to otherwise achieve a target supply temperature.

The liquid to liquid heat exchanger 625 may have a primary inlet 627 and a primary outlet 629 defining a primary flow path 631 that crosses a secondary flow path 633 with a secondary inlet 635 and secondary outlet 637. Coolant in the coolant loop 117 may flow through the secondary flow path 633 and undergo cooling in response to crossing liquid introduced at a further reduced temperature into the primary inlet 627. In one illustrative example, the primary inlet 627 may introduce liquid at 24 degrees Celsius while the secondary inlet 635 introduces coolant at 40 degrees Celsius and exchange of heat may allow the coolant to exit the secondary outlet 637 at a reduced temperature of 30 degrees Celsius while liquid exiting the primary outlet 629 may be output at an elevated temperature of approximately 35 degrees Celsius, although other values may be achieved in operation. More generally, a liquid to liquid heat exchanger 625 may provide a larger reduction in temperature compared to a liquid to air heat exchanger 607 in a comparable size of internal volume 605 of the heat exchanging cabinet 601 and thus may be particularly useful for trim cooling or other situations in which a relatively larger reduction in temperature of the coolant in the coolant loop 117 is of use. Moreover, although the liquid to liquid heat exchanger 625 is shown arranged along the supply side portion 619, placement may be implemented along the return side portion 621 additionally or alternatively.

Additionally or alternatively, the heat exchanger 603 may correspond to an energy capture system 616, as at right in FIG. 6, for example. Features described with respect to the liquid to air heat exchanger 607 and/or the liquid to liquid heat exchanger 625 may additionally or alternatively be implemented with the energy capture system 616 and thus various reference numbers are repeated without duplication of associated description for sake of conciseness.

The internal volume 605 of the heat exchanging cabinet 601 may include components of the energy capture system 616 and/or components for coupling with the energy capture system 616 (e.g., a connection interface). The energy capture system 616 may include suitable components for harnessing energy from heat conveyed by the coolant (e.g., in the return side 121) from the heat-generating components or appliances 309. Thus, the energy capture system 616 may at least partially reduce a temperature of coolant in the coolant loop 117 in use.

Some examples of suitable structure for the energy capture system 616 may include thermoelectric generators or liquid to liquid heat exchangers. In various embodiments, an energy recovery loop may extract the heat from the coolant for reuse and/or improvement in efficiency. As one example, heat obtained by the energy capture system 616 may be used as heat for a desiccant system (e.g., which may facilitate drying of air within the datacenter), although other uses of the reclaimed heat may be utilized.

Although the energy capture system 616 is shown at right in FIG. 6 implemented individually in a heat exchanging cabinet 601, the energy capture system 616 may be implemented as a supplement for other cabinets 103 additionally or alternatively. For example, the components of the energy capture system 616 and/or suitable interfaces for connecting thereto may be included as a supplement with a liquid to air heat exchanger 607 (e.g., as at 616A at left in FIG. 6), with a liquid to liquid heat exchanger 625 (e.g., as at 616B at middle in FIG. 6), with a pressure imparting cabinet 501 (e.g., as at 516 in FIG. 5), and/or with a coolant distributing cabinet 401 (e.g., as at 416 in FIG. 4). Placing structure for the energy capture system 616 in the coolant distributing cabinet 401 (e.g., as at 416 in FIG. 4) may allow the energy to be captured at a location near the source of heat (e.g., near where coolant is received after absorbing heat from the racks 301 and/or the heat-generating components or appliances 309) and thus may enable efficient energy harvesting accordingly.

Similarly, although the liquid to liquid heat exchanger 625 is shown at middle in FIG. 6 implemented individually in a heat exchanging cabinet 601, the liquid heat exchanger 625 may be implemented as a supplement for other cabinets 103 additionally or alternatively. By way of example, an interface and/or components for a trim cooling system or other liquid heat exchanger 625 may be included in any location just described as options for the energy capture system 616 (e.g., at 616A, 516, 416, or in other locations, such as along the supply side 119 instead of along the return side 121). In some examples, control valves 408 in the coolant distributing cabinet 401 can be utilized to achieve mixing of multiple flow streams at different temperatures (e.g., colder coolant can be circulated through an additional flow loop that may be available for trim cooling etc. and may be mixed into a primary stream to lower the supply temperature when warranted).

FIG. 7 is a schematic representation of some examples of coolant loops 117 that may be formed for implementation by the modular system 101. The view 710 shows a coolant loop 117 formed with two coolant distribution cabinets 401, one pressure imparting cabinet 501, and three heat exchanging cabinets 601 (which each include a liquid to air heat exchanger 607), while the view 711 shows a coolant loop 117 formed with one coolant distribution cabinet 401, one pressure imparting cabinet 501, and three heat exchanging cabinets 601 (where two include a liquid to air heat exchangers 607 and one includes a liquid to liquid heat exchanger 625). Some parts are shown in FIG. 7 with fewer internal features than in previous figures for ease of viewing, although more, fewer, or other features may be implemented in use. As one example of a further variation, line 715 may represent a wall, juncture, or other boundary, e.g., such that a first alternate coolant distribution cabinet 401A is included with a manifold 403, while a second alternate coolant distribution cabinet 401B is included with an interface to engage a catcher system 217, although other cabinets 103 can be included with fewer, more, or other parts than the full and/or exact combinations shown and/or described herein.

FIG. 7 generally illustrates that coolant loops 117 may be established with one or more of any form of cabinet 103. In various embodiments, a selected number of a given type of cabinet may include a number selected to achieve at least a related threshold. As one example, the modular system 101 may include a number of one or more pressure imparting cabinets 501 selected to achieve at least a threshold amount of pressure within the coolant loop 117. As another example, the modular system 101 may include a number of one or more heat exchanging cabinets 601 selected to achieve at least a threshold amount of heat exchanging capacity within the coolant loop 117 (and may include one or more types, such as selected from those including a liquid to air heat exchanger 607 and/or from those including a liquid to liquid heat exchanger 625). As a further example, the modular system 101 may include a number of one or more coolant distributing cabinets 401 selected to achieve at least a threshold amount of coolant distributing capacity within the coolant loop 117 (such as to enable servicing and/or routing of coolant for a threshold number of racks 301 and/or included components or appliances 309).

Based on the disclosure and teachings provided herein, a person of ordinary skill in the art will appreciate other ways and/or methods to implement the various embodiments. The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Various embodiments of this disclosure are described herein, including the best mode known to the inventors for carrying out the disclosure. Variations of those embodiments may become apparent to those of ordinary skill in the art upon reading the foregoing description. The inventors expect skilled artisans to employ such variations as appropriate and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

What is claimed is:

1. A method of establishing circulation availability of liquid coolant for datacenter components, the method comprising:
accessing cabinets of a modular system that includes coolant distributing cabinets, pressure imparting cabinets, and heat exchanging cabinets, each of the cabinets including couplers that include a supply inlet, a supply outlet, a return inlet, and a return outlet;
installing a selected number of cabinets in a row between a hot aisle and a cold aisle of a datacenter, the selected number including at least a first coolant distributing cabinet, at least a first pressure imparting cabinet, and at least a first heat exchanging cabinet; and
connecting the couplers to establish a coolant loop extending through the cabinets and configured to circulate coolant through the coolant loop in response to pressure from a pump in the first pressure imparting cabinet such that coolant travels along a supply side of the coolant loop to one or more racks of components connected with a manifold in the first coolant distributing cabinet and carries heat from said components along a return side of the coolant loop to a heat exchanger in the first heat exchanging cabinet for heat dissipation by receiving cooling air flow directed from the cold aisle toward the hot aisle across the heat exchanger so as to ready coolant for travel anew along the supply side.

2. The method of claim 1, further comprising adding a first number of coolant distributing cabinets to increase an amount of coolant distributing capacity within the coolant loop.

3. The method of claim 2, further comprising adding a second number of pressure imparting cabinets to increase an amount of pressure capacity within the coolant loop.

4. The method of claim 3, further comprising adding a third number of heat exchanging cabinets to increase an amount of heat exchanging capacity within the coolant loop.

5. A datacenter, comprising:
a row between a hot aisle and a cold aisle;
a modular system including a set of cabinets each having couplers that include a supply inlet, a supply outlet, a return inlet, and a return outlet, wherein the couplers are configured to be connected to establish a coolant loop extending through the cabinets;
a pressure imparting cabinet included in the set of cabinets and including a pump configured to circulate coolant through the coolant loop;
a coolant distributing cabinet included in the set of cabinets and including a manifold configured to distribute coolant along a supply side of the coolant loop toward a plurality of rack-mounted components and to direct coolant carrying heat from said components into a return side of the coolant loop; and
a heat exchanging cabinet included in the set of cabinets and comprising a heat exchanger arranged between the hot aisle and the cold aisle so as to be positioned for receiving cooling air flow directed from the cold aisle toward the hot aisle across the heat exchanger for dissipating heat carried in the coolant loop so as to ready coolant for use along the supply side.

6. The datacenter of claim 5, further comprising at least one of:
a plurality of rack-mounted components; or
a plurality of racks for supporting the plurality of rack-mounted components.

7. The datacenter of claim 5, wherein the modular system includes a number of one or more pressure imparting cabinets selected to achieve at least a threshold amount of pressure within the coolant loop.

8. The datacenter of claim 5, wherein the modular system includes a number of one or more heat exchanging cabinets selected to achieve at least a threshold amount of heat exchanging capacity within the coolant loop.

9. The datacenter of claim 5, wherein the modular system includes a number of one or more coolant distributing cabinets selected to achieve at least a threshold amount of coolant distributing capacity within the coolant loop.

10. The datacenter of claim 5, further comprising a catcher system comprising:
a catcher pressure imparting cabinet;
a catcher heat exchanging cabinet connected in a catcher coolant loop with the catcher pressure imparting cabinet; and
a liquid-conveying network comprising a plurality of conduits and valves arranged to selectively fluidly couple the catcher coolant loop with the coolant loop and/or one or more other loops such that the catcher coolant loop is selectively engageable for supplemental capacity of pressure and/or heat exchanging.

11. A modular system, comprising:
a set of cabinets configured to be coupled together to form a coolant loop having a supply side and a return side;
at least one pressure imparting cabinet included in the set of cabinets and including a pump configured to circulate coolant through the coolant loop;
at least one coolant distributing cabinet included in the set of cabinets and including a manifold configured to distribute coolant along the supply side of the coolant loop toward a plurality of rack-mounted components and to direct coolant carrying heat from said components into the return side of the coolant loop; and
at least one heat exchanging cabinet included in the set of cabinets and comprising a heat exchanger arranged for dissipating heat carried in the coolant loop so as to ready the coolant for use along the supply side.

12. The modular system of claim 11, wherein at least one of:
1) each cabinet in the set of cabinets includes couplers that include a supply inlet, a supply outlet, a return inlet, and a return outlet, wherein the couplers are configured to be connected to establish a coolant loop extending through the cabinets; or
2) the cabinets are configured to be installed in a row between a hot aisle and a cold aisle of a datacenter.

13. The modular system of claim 11, wherein at least one of:
1) each cabinet in the set of cabinets includes a shell defining outermost boundaries of the cabinet that are sized to fit within a slot sized to match a single instance of a rack width or a multiple of the rack width;
2) each cabinet in the set of cabinets is sized to fit within a rack height; or
3) each cabinet in the set of cabinets is sized to fit within a rack depth.

14. The modular system of claim 11, further comprising:
a pressure imparting cabinet comprising:
a shell defining an internal volume;
a supply side portion of a supply side of a coolant loop, the supply side portion extending within the shell between a supply side inlet and a supply side outlet configured for coupling to extend the coolant loop outside the internal volume;
a return side portion of a return side of the coolant loop, the return side portion extending within the shell between a return side inlet and a return side outlet configured for coupling to extend the coolant loop outside the internal volume; and
a pump located within the internal volume, included in the supply side portion or the return side portion, and configured to circulate coolant through the coolant loop.

15. The modular system of claim 14, further comprising at least one of:
1) a controller within the internal volume and configured for controlling at least one of components within the internal volume or components in another cabinet couplable with the pressure imparting cabinet;
2) an air separator;
3) a monitoring sensor configured to measure at least one of coolant quality, pressure, temperature, or flow rate;
4) an expansion tank;
5) a filter;
6) a coolant filling system; or
7) a set of valves configured for balancing flow among differing paths.

16. The modular system of claim 11, further comprising:
a heat exchanging cabinet comprising:
a shell defining an internal volume;
a supply side portion of a supply side of a coolant loop, the supply side portion extending within the shell between a supply side inlet and a supply side outlet configured for coupling to extend the coolant loop outside the internal volume;
a return side portion of a return side of the coolant loop, the return side portion extending within the shell between a return side inlet and a return side outlet configured for coupling to extend the coolant loop outside the internal volume; and
a heat exchanger located within the internal volume and arranged for dissipating heat carried in the coolant loop so as to ready the coolant for use along the supply side.

17. The modular system of claim 16, wherein the heat exchanger comprises:
a liquid to air heat exchanger; or
a liquid to liquid heat exchanger.

18. The modular system of claim 16, further comprising at least one of:
1) a return outlet valve and a supply inlet valve operable so that when both closed an end of the coolant loop is formed by the heat exchanging cabinet;
2) a fan positioned to draw air across the heat exchanger;
3) a fan positioned to draw air from a cold aisle of a datacenter, across the heat exchanger, and into a hot aisle of the datacenter; or
4) a fan adjustable to modulate airflow across the heat exchanger to modulate an amount of cooling imparted by the heat exchanger in response to a sensor positioned upstream in a different cabinet.

19. The modular system of claim 11, further comprising:
a coolant distributing cabinet comprising:
a shell defining an internal volume;
a supply side portion of a supply side of a coolant loop, the supply side portion extending within the shell between a supply side inlet and a supply side outlet configured for coupling to extend the coolant loop outside the internal volume;
a return side portion of a return side of the coolant loop, the return side portion extending within the shell between a return side inlet and a return side outlet configured for coupling to extend the coolant loop outside the internal volume; and
a manifold configured to be installed relative to a plurality of rack-mounted components so as to distribute coolant along the supply side of the coolant loop toward said components and to direct coolant carrying heat from said components into the return side of the coolant loop.

20. The modular system of claim 16, further comprising at least one of:
1) a catcher inlet and a catcher outlet arranged to selectively fluidly couple the coolant loop with a catcher coolant loop such that the catcher coolant loop is selectively engageable for supplemental capacity of pressure and/or heat exchanging;
2) flexible hoses or piping extending between the manifold and the plurality of rack-mounted components so that each rack-mounted component has a supply line providing coolant flow from the supply side of the coolant loop and a return line providing coolant flow with heat from the component into the return side of the coolant loop;
3) at least one valve configured to modulate flow rate between the coolant distributing cabinet at least one rack-mounted component;
4) at least one mixing valve configured to modulate amounts of flow at different temperatures to control output coolant toward a target temperature;
5) at least one sensor configured to provide information about temperature in the return side to facilitate downstream modulation of a heat exchanger in a different cabinet; or
6) an energy capture system component or connection interface included in the internal volume.
